(19) United States
(12) Patent Application Publication
(10) Pub. No.: US 2026/0185232 A1
(43) Pub. Date: Jul. 2, 2026

(54) SUBSTRATE PROCESSING APPARATUS

(71) Applicant: TES CO., LTD, Yongin-si (KR)

(72) Inventors: Kyung-Ho JANG, Yongin-si (KR); Min-Wook KANG, Yongin-si (KR); Byeong-Ho YUN, Yongin-si (KR)

(73) Assignee: TES CO., LTD, Yongin-si (KR)

(21) Appl. No.: 19/423,883

(22) Filed: Dec. 17, 2025

(30) Foreign Application Priority Data
Dec. 27, 2024 (KR) 10-2024-0199374

(51) Int. Cl. C23C 16/455; C23C 16/44; C23C 16/507

(52) U.S. Cl. CPC C23C 16/45565; C23C 16/4408; C23C 16/4557; C23C 16/507

(57) ABSTRACT

A substrate processing apparatus includes a chamber, an upper showerhead plate, and a substrate supporting unit. The chamber provides a processing space for a substrate. The upper showerhead is provided in an upper region of an interior of the chamber to supply purge gas toward an upper surface of the substrate. The substrate supporting unit is provided in a lower region of the interior of the chamber to support a periphery of a lower surface of the substrate. The substrate supporting unit includes a metal lower showerhead assembly that supplies at least one of process gas and cleaning gas toward the lower surface of the substrate.

### CROSS-REFERENCE TO RELATED APPLICATIONS

A claim for priority under 35 U.S.C. § 119 is made to Korean Patent Application No. 10-2024-0199374 filed on December 27, 2024, in the Korean Intellectual Property Office, the entire contents of which are hereby incorporated by reference.

### BACKGROUND OF THE INVENTION

### FIELD OF THE INVENTION

The present invention relates to a substrate processing apparatus, and more particularly to the substrate processing apparatus capable of more effectively cleaning a lower portion of a substrate, preventing deformation of a showerhead, and preventing leakage of RF power.

### DESCRIPTION OF THE RELATED ART

In general, when a thin film is deposited on an upper surface (or a top surface) of a substrate, the thin film can cause stress on the substrate, which can cause the substrate to deflect. As a result, it is difficult to smoothly proceed with various subsequent processes on the substrate. Therefore, a thin film with equivalent stress is deposited on a lower surface (or a bottom surface) of the substrate to reduce deflection of the substrate.

As such, an apparatus for depositing the thin film on the lower surface of the substrate is provided with a showerhead mechanism that supplies gas not only to the upper surface of the substrate but also to the lower surface of the substrate.

A lower showerhead located below the substrate was likely to be deformed due to temperature. In addition, when plasma is used in the process on the substrate, RF power could be lost through a chamber rather than between the substrate and the lower showerhead. Furthermore, for the apparatus depositing the thin film on the lower surface of the substrate, particles and other debris can form on the lower surface of the substrate, and cleaning was less effective when cleaning gas is supplied by a showerhead located above the substrate.

### SUMMARY OF THE INVENTION

The embodiments disclosed herein have been contemplated to solve problems in the prior art mentioned above. Thus, it is an object of the present invention to provide a substrate processing apparatus capable of reducing deformation of a lower showerhead located below a substrate according to temperature, and further capable of effectively transferring heat to a lower portion of the substrate.

Further, it is an object of the present invention to provide a substrate processing apparatus capable of maximally inducing RF power between the substrate and the lower showerhead when plasma is used, and maximally suppressing leakage of the RF power into a chamber.

Further, it is an object of the present invention to provide a substrate processing apparatus capable of improving cleaning efficiency by supplying cleaning gas to a lower portion of the substrate, and reducing particles caused by mixing of the cleaning gas and the process gas, as much as possible.

To achieve the above object, the present invention may provide a substrate processing apparatus comprising: a chamber configured to provide a processing space for a substrate; an upper showerhead provided in an upper region of an interior of the chamber and configured to supply purge gas toward an upper surface of the substrate; and a substrate supporting unit provided in a lower region of the interior of the chamber and configured to support a periphery of a lower surface of the substrate, the substrate supporting unit including a metal lower showerhead assembly configured to supply at least one of process gas and cleaning gas toward the lower surface of the substrate.

Here, the metal lower showerhead assembly may include: a metal faceplate formed with a plurality of supply holes that are configured to supply the at least one of the process gas and the cleaning gas toward the lower surface of the substrate; and a metal lower heater disposed below the metal faceplate, the metal lower heater being configured to support the metal faceplate and to heat the substrate.

Further, the metal faceplate may be disposed to be spaced apart from the metal lower heater, and may include a support standoff configured to support the metal faceplate and to connect the metal faceplate and the metal lower heater.

Moreover, the support standoff may be provided to any one of the metal faceplate and the metal lower heater, and may extend toward the other thereof to which a fastening member that secures an end portion of the support standoff is fastened.

Further, both end portions of the support standoff may be fixed to the metal faceplate and the metal lower heater, respectively.

Meanwhile, the substrate processing apparatus may further comprise: an insulator configured to electrically insulate the metal lower showerhead assembly from the chamber; and an RF regulator connected to the metal lower showerhead assembly and configured to adjust a capacitance of the metal lower showerhead assembly.

In this case, the substrate processing apparatus may further comprise a lower supply line connected to a drive shaft of the metal lower showerhead assembly and configured to supply the process gas or the cleaning gas. The lower supply line may pass through the insulator and may be connected to the RF regulator below the chamber.

Further, the substrate processing apparatus may further comprise an RF rod connecting the drive shaft and the RF regulator.

Moreover, the substrate processing apparatus may further comprise: a first supply channel connected to the metal lower showerhead assembly and configured to supply the process gas; and a second supply channel connected to the metal lower showerhead assembly configured to supply the cleaning gas.

In this case, the first supply channel may be connected to a central region of the metal lower showerhead assembly, and the second supply channel may be disposed to be adjacent to the first supply channel.

Further, the second supply channel may be connected to a remote plasma source (RPS).

Details of examples or implementations will be described in the following with reference to the accompanying drawings. Other features will be apparent from the description and drawings, and from the claims.

### BRIEF DESCRIPTION OF THE DRAWINGS

The present invention will become more fully understood from the detailed description given below and the accompanying drawings, which are given by illustration only, and thus are not intended to limit the scope of the present Invention, wherein:

FIG. 1 is a side sectional view of a substrate processing apparatus according to one embodiment of the present invention;

FIG. 2 is an enlarged side sectional view of a metal faceplate and a metal lower heater;

FIG. 3 is a partially enlarged side sectional view of the dotted area of FIG. 2, showing a more enlarged view of a lower supply line; and

FIG. 4 is a side sectional view of a substrate processing apparatus according to another embodiment of the present invention.

### DETAILED DESCRIPTION OF THE PREFERRED EMBODIMENT

Description for the present invention will now be given in detail according to examples disclosed herein, with reference to the accompanying drawings.

For the sake of a brief description with reference to the drawings, the same or equivalent components may be provided with the same reference numbers, and description thereof will not be repeated. In the following, any conventional art which is well-known to one of ordinary skill in the relevant art has generally been omitted for the sake of brevity. The accompanying drawings are used to help easily understand various technical features and it should be understood that the examples presented herein are not limited by the accompanying drawings. As such, the present invention should be construed to extend to any alterations, equivalents, and substitutes in addition to those which are particularly set out in the accompanying drawings.

A singular representation may include a plural representation unless it represents a definitely different meaning from the context.

It will be understood that although the terms “first,” “second,” etc., may be used herein to describe various components, these components should not be limited by these terms. These terms are only used to distinguish one component from another component.

It should be understood that when a component is referred to as being “connected to” or “coupled to” another component, this component may be directly connected to or coupled to another component, or any intervening components may be present between the components. In contrast, when a component is referred to as being “directly connected to” or “directly coupled to” another component, there are no intervening components present.

Terms such as "comprise", “include” or “have” are used herein and should be understood that they are intended to indicate an existence of several components, functions or steps, disclosed in the specification, and it is also understood that greater or fewer components, functions, or steps may likewise be utilized. Moreover, due to the same reasons, it is also understood that the present invention includes any combinations of features, numerals, steps, operations, components, parts and the like partially omitted from the related or involved features, numerals, steps, operations, components, and parts described using the aforementioned terms unless deviating from the intentions of the original disclosure.

Hereinafter, a configuration of a substrate processing apparatus according to an embodiment of the present invention will be specifically described with reference to drawings.

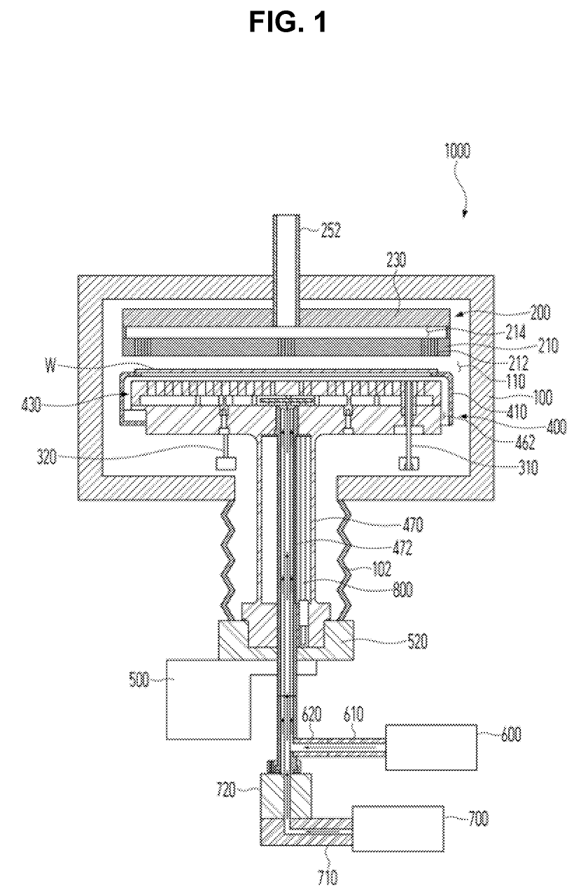

FIG. 1 is a side sectional view of the substrate processing apparatus 1000 according to one embodiment of the present invention.

Referring to FIG. 1, the substrate processing apparatus 1000 may comprise a chamber 100 providing a processing space 110 for a substrate W, an upper showerhead 200 provided in an upper region of an interior of the chamber 100 to supply purge gas toward an upper surface of the substrate W, and a substrate supporting unit 400 provided in a lower region of the interior of the chamber 100 to support a periphery of a lower surface of the substrate W and including a metal lower showerhead assembly 430 that supplies at least one of process gas and cleaning gas toward the lower surface of the substrate W. Hereinafter, any upper portions (including an upper surface, an upper end, and the like) of any components may indicate corresponding top portions thereof, and likewise, any lower portions of any components may also indicates corresponding bottom portions thereof.

Firstly, the substrate processing apparatus 1000 may include the chamber 100 that provides the processing space 110 therein.

The chamber 100 may provide the processing space 110 in the interior thereof, in which a deposition process for the substrate W is performed.

An upper region of the interior of the chamber 100 may be provided with the upper showerhead 200 for supplying the purge gas that includes inert gas and the like toward the upper surface of the substrate W.

The upper showerhead 200 may include an upper showerhead plate 210. The upper showerhead 200 may further include an upper heater 230 provided on an upper portion of the upper showerhead plate 210. The upper showerhead plate 210 may be provided with a plurality of upper through holes 212. Meanwhile, although not shown in the drawings, the upper showerhead 200 may be configured to be raised upwardly and lowered downwardly.

At an upper portion of the chamber 100, an upper supply line 252 to which the inert gas and the like is supplied, may be connected. The inert gas supplied along the upper supply line 252 may be supplied through an upper diffuser 214, and then through the upper showerhead plate 210, to the upper surface of the substrate W.

The upper showerhead 200 may be connected to an RF power supply (not shown) so that RF power may be supplied. In this case, the upper showerhead 200 may serve as a first electrode, and a substrate supporting unit 400 which will be described below may be grounded to serve as a second electrode.

In addition, although not shown in the drawings, a configuration in which the RF power supply is connected to the substrate supporting unit 400 and the upper showerhead 200 is grounded is also possible. That is, the RF power supply may be connected to any one of the upper showerhead 200 and the substrate supporting unit 400, and the other of the upper showerhead 200 and the substrate supporting unit 400 may be grounded.

Meanwhile, the lower region of the interior of the chamber 100 may be provided with the substrate supporting unit 400 on which the substrate W is seated and supported.

The substrate supporting unit 400 may be configured to be movable upwardly and downwardly in a lower region of the processing space 110, and may support the periphery of the lower surface of the substrate W to expose the lower surface of the substrate W to the process gas.

The substrate supporting unit 400 may be connected to a drive shaft 470 extending downwardly, and the drive shaft 470 may be connected to a drive unit (not shown), such as a motor or the like, such that the drive shaft 470 and substrate supporting unit 400 are moved up and down by operating the drive unit.

In this case, a lower portion of the chamber 100 may be provided with a bellows 102 extending downwardly, and the drive shaft 470 may be disposed in an interior of the bellows 102.

Specifically, the substrate supporting unit 400 may include a substrate holder 410 supporting the lower surface of the periphery of the substrate W, and the metal lower showerhead assembly 430 provided at the lower region of the interior of the chamber 100 to supply at least one of the process gas and the cleaning gas towards the lower surface of the substrate W.

The substrate holder 410 may support the lower surface of the periphery of the substrate W. In this case, the metal lower showerhead assembly 430 may be provided in an interior of the substrate holder 410.

In the present invention, the metal lower showerhead assembly 430 may be made up of metal to serve as an electrode for plasma generation, and may be made up of aluminum or the like, for example. Further, the substrate holder 410 may be configured as a non-conductor, and may be made of ceramic material, for example.

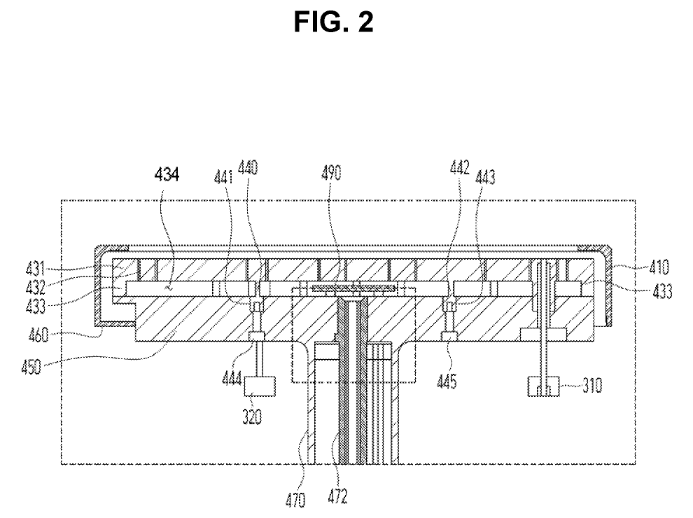

FIG. 2 is an enlarged side sectional view of a metal faceplate 431 and a metal lower heater 450 of the substrate supporting unit 400.

Referring to FIGS. 1 and 2, the metal lower showerhead assembly 430 may include a metal faceplate 431 formed with a plurality of supply holes 432 that supply at least one of the process gas and the cleaning gas toward the lower surface of the substrate W, and a metal lower heater 450 disposed below the metal faceplate 431 to support the metal faceplate 431 and heating the substrate W.

A plurality of lift pins 310, 320 may be disposed with passing through the metal lower showerhead assembly 430, and upper end portions of the lift pins 310, 320 may protrude upon raising and lowering of the substrate supporting unit 400 to support the substrate W and thus may load the substrate W to the substrate holder 410 or unload the substrate W from the substrate holder 410.

The metal lower heater 450 may serve to heat the metal faceplate 431 while simultaneously supporting the metal faceplate 431 and the substrate holder 410. In this case, a power line 800 may be disposed along an interior of the drive shaft 470 to provide power to the metal lower heater 450.

In this case, the metal faceplate 431 may be connected to an upper surface of the metal lower heater 450 and a lower supply line 472 through which the process gas or the like is supplied may be connected to a lower diffuser 434 by passing through the drive shaft 470 and the metal lower heater 450.

Further, a fixture (or a fixing member) 460 that supports a lower end portion of the substrate holder 410 may be connected to the metal lower heater 450.

In this case, the fixing member 460 do not completely seal and couple the lower end portion of the substrate holder 410 and the metal substrate heater 450. Instead, a plurality of the fixing members 460 may be provided and spaced apart at predetermined interval along an outer circumference of the metal substrate heater 450.

That is, when the plurality of fixing members 460 are provided, spaces between neighboring fixing members 460 may be open downward to communicate with the interior of the chamber 100. Thus, a space between side surfaces of the metal faceplate 431 and the metal lower plate 450 and the inner opposite surface of the substrate holder 410 may form an exhaust channel 462.

In this case, the process gas supplied from the metal faceplate 431 may be discharged through the exhaust channel 462 to the lower region of the interior of the chamber 100, and may be exhausted to an exterior of the chamber 100 through an exhaust outlet (not shown) provided at the lower portion of the chamber 100.

Also, although not shown in the drawings, the substrate holder 410 may be configured in the form of a ring rather than a column and may be supported spaced apart from the upper surface of the metal faceplate 431. In this case, the fixing members 460 may be disposed on the upper surface of the metal faceplate 431, and may form a gap between the ring-shaped substrate holder and the upper surface of the metal faceplate 431.

Meanwhile, as shown in FIG. 2, the metal faceplate 431 is disposed spaced apart from the metal lower heater 450, and the lower diffuser 434 as described above may be formed between the metal faceplate 431 and the metal lower heater 450.

The lower diffuser 434 may be provided with a baffle 490 to disperse and supply the process gas or the cleaning gas supplied via the lower supply line 472.

In this case, a support portion 433 that protrudes downwardly may be formed along an edge of a lower surface of the metal faceplate 431. A lower end portion of the support portion 433 may rest on the metal lower heater 450 to support the metal faceplate 431.

Further, between the metal faceplate 431 and the metal lower heater 450, there may be at least one support standoff 440, 442 that supports the metal faceplate 431 and connects the metal faceplate 431 and the metal lower heater 450.

The support standoffs 440, 442 may support the metal faceplate 431, and thus may prevent deformation of the metal faceplate 431.

Further, the support standoffs 440, 442 may serve to allow heat from the metal lower heater 450 to be transferred to the metal faceplate 431 via heat conduction, and thus may heat the metal faceplate 431 more effectively.

The number of the support standoffs 440, 442 is not particularly limited and may be adjusted appropriately to account for the size, diameter, weight, or thickness of the metal faceplate 431.

The support standoffs 440, 442 may be provided on any one of the metal faceplate 431 and the metal lower heater 450, and may extend toward the other thereof to be engaged with fastening members 444, 445 that secure end portions of the support standoffs 440, 442.

For example, the support standoffs 440, 442 may be formed extending from the lower surface of the metal faceplate 431 towards the metal lower heater 450. In this case, the metal lower heater 450 may be formed with recesses 441, 443 into which lower end portions of the support standoffs 440, 442 are inserted and connected. When the lower end portions of the support standoffs 440, 442 are inserted into the recesses 441, 443, the fastening members 444, 445 comprising bolts or the like that penetrate the metal lower heater 450, may be fastened to the lower end portions of the support standoffs 440, 442 to connect the support standoffs 444, 445 and the metal lower heater 450.

As such, when the metal faceplate 431 and the metal lower heater 450 are fastened in a detachable configuration, it becomes available to easily separate the metal faceplate 431 from the metal lower heater 450. In this case, when maintenance of the interior of the metal lower showerhead assembly 430 is required, such as maintenance of the baffle 490 or the like, work may be facilitated by separating the metal faceplate 431 from the metal lower heater 450.

Meanwhile, although not shown in the drawings, both end portions of the support standoffs 440, 442 may be fixed to both the metal faceplate 431 and the metal lower heater 450. For example, the support standoffs 440, 442 may be formed extending from the lower surface of the metal faceplate 431 toward the metal lower heater 450, and the lower end portions of the support standoffs 440, 442 may be fixed to the metal lower heater 450 by welding or the like.

Meanwhile, referring to FIG. 1, the process gas or the cleaning gas is supplied via the lower supply line 472 that passes through the drive shaft 470, and the process gas or cleaning gas supplied along the lower supply line 472 is supplied to the metal faceplate 431 via the lower diffuser 434. The process gas supplied to the metal faceplate 431 may be supplied to the lower surface of the substrate W through the lower through hole 432.

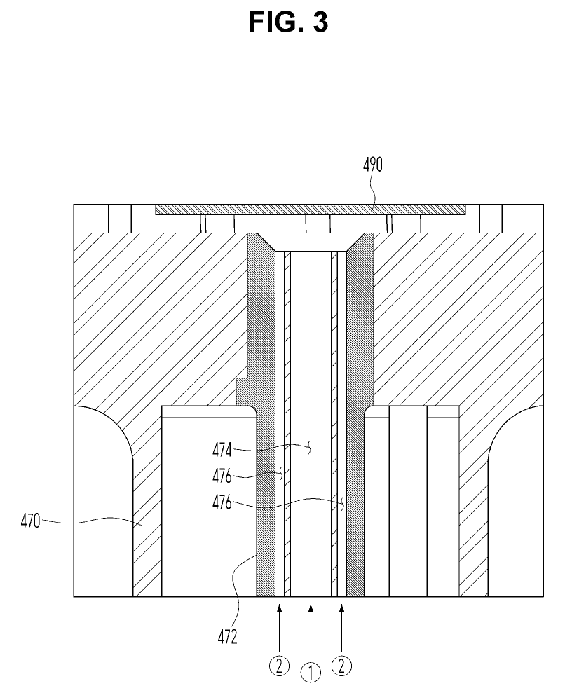

FIG. 3 is a partially enlarged side sectional view of the dotted area of FIG. 2, showing a more enlarged view of the lower supply line 472.

Referring to FIGS. 1 to 3, the lower supply line 472 may include a first supply channel 474 connected to the metal lower showerhead assembly 430 to supply the process gas, and a second supply channel 476 connected to the metal lower showerhead assembly 430 to supply the cleaning gas.

That is, in the present invention, the supply channel through which the process gas is supplied and the supply channel through which the cleaning gas is supplied are distinguished or separated from each other, so that the generation of particles by mixing the process gas and the cleaning gas may be suppressed as much as possible.

In this case, the first supply channel 474 may be connected to a central region of the metal lower showerhead assembly 430, and the second supply channel 476 may be adjacent to the first supply channel 474 and arranged to surround the first supply channel 474.

The first supply channel 474 may be connected to a process gas source 700 to be supplied with the process gas. For example, the process gas source 700 may be connected to the first supply channel 474 via a first connection channel 710.

Further, the second supply channel 476 may be connected to a remote plasma source (RPS) 600 to be supplied with the cleaning gas in the form of a remote plasma. For example, the RPS 600 may be connected to the second supply channel 476 via a second connection channel 610.

In this manner, the cleaning gas may be supplied to the lower portion of the substrate W via the second supply channel 476 to increase the cleaning effectiveness of the lower portion of the substrate W, compared to the supplying of the cleaning gas from the upper portion of the substrate W.

During processing of the substrate W, the process gas may be supplied through the first supply channel 474, such that process gas may be supplied toward the lower surface of the substrate W.

In this case, when the RF power supply is connected to the upper showerhead 200, the lower showerhead assembly 430 may be grounded to generate the plasma between the substrate W and the lower showerhead assembly 430.

Meanwhile, the substrate processing apparatus 1000 according to the embodiments described above may include an RF regulator 500 to ensure that RF power is transferred to the substrate supporting unit 400 and to reduce as much as possible the transmission of RF power to the chamber 100, when the plasma is generated between the lower surface of the substrate W and the metal lower showerhead assembly 430.

The RF regulator 500 may be electrically coupled to the metal lower showerhead assembly 430, and by operation of the RF regulator 500, a capacitance of the metal lower showerhead assembly 430 may be adjusted to induce a relatively greater RF current into the metal lower showerhead assembly 430.

The RF regulator 500 may be configured as a so-called “analog tuner” and may have a configuration that allows the capacitance to be adjusted by manipulating a variable capacitance diode provided therein.

Thus, the RF regulator 500 may be manipulated to adjust the capacitance of the metal lower showerhead assembly 430 such that relatively more RF current is induced toward the metal lower showerhead assembly 430 rather than toward walls of the chamber 100.

In this case, the metal lower showerhead assembly 430 may have a first insulator 520 insulating the chamber 100 from the drive shaft 470 of the metal lower showerhead assembly 430, and the lower supply line 472 may penetrate the first insulator 520 to be connected to the RF regulator 500 below the chamber 100.

In addition, a second insulator 720 and a third insulator 620 may be provided between the process gas source 700 and the lower supply line 472, and between the RPS 600 and the lower supply line 472, respectively.

In this case, the second insulator 720 may be provided between the first supply channel 474 and the first connection channel 710. Further, the third insulator 620 may be provided between the second supply channel 476 and the second connecting channel 610.

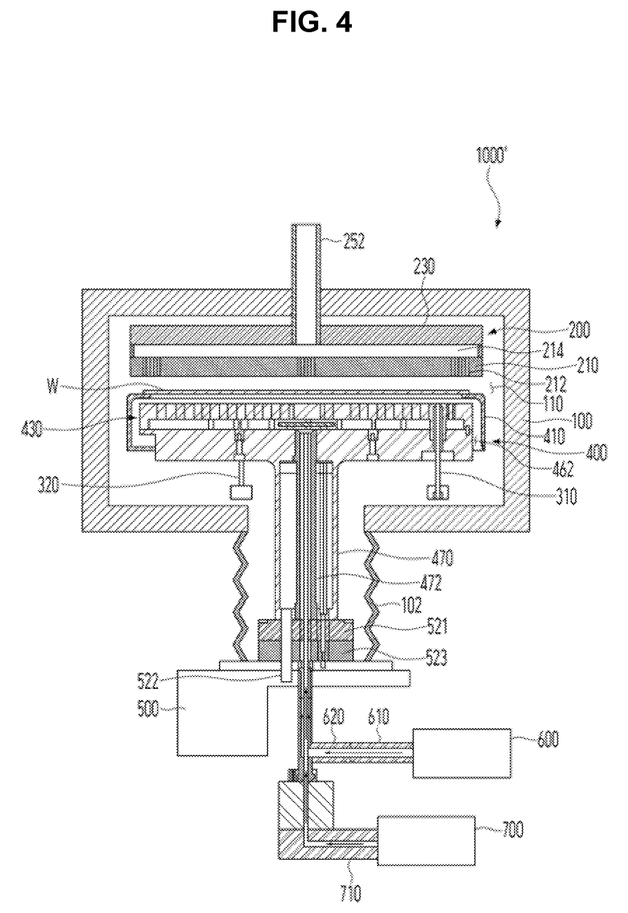

Meanwhile, FIG. 4 illustrates a substrate processing apparatus 1000' according to another embodiment. In FIG. 4, the same reference numerals are used for the same components as those described above in FIG. 1.

Referring to FIG. 4, the RF regulator 500 may be connected to the drive shaft 470 and the metal lower showerhead assembly 430 via an RF rod 522.

In this case, a first insulator 521 is connected to a lower end portion of the drive shaft 470. The first insulator 521 may be connected to the chamber 100 via a connector 523.

The substrate processing apparatus according to the embodiments described above has the technical advantages as follows.

According to the embodiments disclosed herein having the configuration described above, the temperature (or heat) transfer effect can be enhanced by making the lower showerhead located below the substrate with metal, and the deformation of the lower showerhead can be reduced by the support standoff. Furthermore, the substrate can be heated more effectively by transferring the heat by the heat conduction using the support standoff.

In addition, when the plasma is used, the RF regulator can maximally induce the RF power between the substrate and the lower showerhead and maximally suppress the leakage of the RF power into the chamber in order to enhance the plasma effect.

Moreover, the efficiency of cleaning can be improved by supplying the cleaning gas to the lower portion of the substrate, and the particles caused by mixing of the cleaning gas and the process gas can be reduced as much as possible by separating the channels of the cleaning gas and the process gas.

Although a number of examples have been described, it should be understood that other modifications and implementations can be devised by those skilled in the art that will fall within the spirit and scope of the principles of the present invention. More particularly, various variations and modifications in the structure or the configuration are possible within the scope of the disclosure, the drawings, and the appended claims. In addition to variations and modifications in the configuration, alternative uses will also be apparent to those skilled in the art.

What is claimed is:

1. A substrate processing apparatus comprising:
a chamber configured to provide a processing space for a substrate;
an upper showerhead provided in an upper region of an interior of the chamber and configured to supply purge gas toward an upper surface of the substrate; and
a substrate supporting unit provided in a lower region of the interior of the chamber and configure to support a periphery of a lower surface of the substrate, the substrate supporting unit including a metal lower showerhead assembly configured to supply at least one of process gas and cleaning gas toward the lower surface of the substrate.

2. The substrate processing apparatus of claim 1, wherein the metal lower showerhead assembly includes:
a metal faceplate formed with a plurality of supply holes that are configured to supply the at least one of the process gas and the cleaning gas toward the lower surface of the substrate; and
a metal lower heater disposed below the metal faceplate, the metal lower heater being configured to support the metal faceplate and to heat the substrate.

3. The substrate processing apparatus of claim 2, wherein the metal faceplate is disposed to be spaced apart from the metal lower heater, and includes at least one support standoff configured to support the metal faceplate and to connect the metal faceplate and the metal lower heater.

4. The substrate processing apparatus of claim 3, wherein the support standoff is provided to any one of the metal faceplate and the metal lower heater, and extends toward the other thereof to which a fastening member that secures an end portion of the support standoff is fastened.

5. The substrate processing apparatus of claim 3, wherein both end portions of the support standoff are fixed to the metal faceplate and the metal lower heater, respectively.

6. The substrate processing apparatus of claim 1, further comprising:
an insulator configured to electrically insulate the metal lower showerhead assembly from the chamber; and
an RF regulator connected to the metal lower showerhead assembly and configured to adjust a capacitance of the metal lower showerhead assembly.

7. The substrate processing apparatus of claim 6, further comprising a lower supply line connected to a drive shaft of the metal lower showerhead assembly and configured to supply the process gas or the cleaning gas,
wherein the lower supply line passes through the insulator and is connected to the RF regulator below the chamber.

8. The substrate processing apparatus of claim 7, further comprising an RF rod connecting the drive shaft and the RF regulator.

9. The substrate processing apparatus of claim 1, further comprising:
a first supply channel connected to the metal lower showerhead assembly and configured to supply the process gas; and
a second supply channel connected to the metal lower showerhead assembly configured to supply the cleaning gas.

10. The substrate processing apparatus of claim 9, wherein the first supply channel is connected to a central region of the metal lower showerhead assembly, and the second supply channel is disposed to be adjacent to the first supply channel.

11. The substrate processing apparatus of claim 9, wherein the second supply channel is connected to a remote plasma source (RPS).
